(19) United States
(12) Patent Application Publication
(10) Pub. No.: US 2026/0173682 A1
(43) Pub. Date: Jun. 18, 2026

(54) Display Device

(71) Applicant: LG Display Co., Ltd., Seoul (KR)

(72) Inventors: Su-Min Lee, Paju-si (KR); Byung-Hyun Lee, Paju-si (KR); Dae-Young Seo, Paju-si (KR); Tae-Yong Kim, Paju-si (KR)

(21) Appl. No.: 19/310,372

(22) Filed: Aug. 26, 2025

(30) Foreign Application Priority Data
Dec. 17, 2024 (KR) 10-2024-0188193

(51) Int. Cl. H10K 59/131; H10K 59/121; H10K 59/80

(52) U.S. Cl. CPC H10K 59/131; H10K 59/1213; H10K 59/873

(57) ABSTRACT

A display device includes: a display panel having a display area and a non-display area adjacent to the display area; aa plurality of signal lines spaced apart from each other in the non-display area; a first planarizing layer under the plurality of signal lines; and a second planarizing layer on the plurality of signal lines, wherein the non-display area includes a scribing area where the first and second planarizing layers are removed, and wherein an end portion of the first planarizing layer and an end portion of the second planarizing layer are disposed at different positions.

### CROSS-REFERENCE TO RELATED APPLICATION

The present application claims the benefit and priority to Republic of Korea Patent Application No. 10-2024-0188193 filed on December 17, 2024, the entire disclosure of which is hereby expressly incorporated by reference for all purposes, as if fully set forth herein.

### TECHNICAL FIELD

The present disclosure relates to a display device, and more particularly, for example, without limitation, to a display device capable of reducing or minimizing electric shortage between signal lines.

### DESCRIPTION OF THE BACKGROUND

Recently, various flat panel display devices such as a liquid crystal display device (LCD), an organic light emitting diode (OLED) display device and a field emission display (FED) device having excellent properties of a thin profile, a light weight and a low power consumption have been developed and applied to various fields.

A display device includes a plurality of signal lines in a non-display area for transmitting power voltages such as a reference signal, a high level signal and a low level signal and driving signals such as a start signal and a clock signal, and the plurality of signal lines are usually disposed between first and second planarizing layers having a relatively great thickness.

The description provided in the background section should not be assumed to be prior art merely because it is mentioned in or associated with the background section. The background section may include information that describes one or more aspects of the subject technology.

### SUMMARY

For easily cutting a substrate, the first and second planarizing layers having a relatively great thickness are removed in a scribing area. It is newly recognized by the inventors of the present disclosure that, since a metal layer of a subsequent process is not completely removed to remain at a step difference portion of the first and second planarizing layers, an electric shortage between the plurality of signal lines may occur.

Accordingly, the present disclosure is directed to a display device that substantially obviates one or more of the problems due to limitations and disadvantages of the related art.

More specifically, the present disclosure is to provide a display device where an electric shortage between a plurality of signal lines due to a residual metal layer is prevented or reduced by disposing end portions of first and second planarizing layers at different positions.

Further, the present disclosure is to provide a display device where an electric shortage between a plurality of signal lines due to a residual metal layer is prevented or reduced by forming an end portion of a first planarizing layer as a zigzag shape.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a display panel having a display area and a non-display area adjacent to the display area; a plurality of signal lines spaced apart from each other in the non-display area; a first planarizing layer under the plurality of signal lines; and a second planarizing layer on the plurality of signal lines, wherein the non-display area includes a scribing area where the first and second planarizing layers are removed, and wherein an end portion of the first planarizing layer and an end portion of the second planarizing layer are disposed at different positions.

In another aspect, a display device may include a substrate having a display area and a non-display area adjacent to the display area; a plurality of signal lines spaced apart from each other in the non-display area; a first planarizing layer under the plurality of signal lines; and a second planarizing layer on the plurality of signal lines, wherein in the non-display area, an end portion of the first planarizing layer and an end portion of the second planarizing layer are disposed at different positions, and the plurality of signal lines extend beyond the end portion of the first planarizing layer and the end portion of the second planarizing layer.

According to embodiments of the present disclosure, since the end portions of the first and second planarizing layers are disposed at different positions, the electric shortage between a plurality of signal lines due to a residual metal layer is minimized, reduced and/or prevented.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

FIG. 1 is a view showing a display device according to one or more example embodiments of the present disclosure;

FIG. 2 is a circuit diagram showing a subpixel of a display device according to one or more example embodiments of the present disclosure;

FIG. 3 is a cross-sectional view showing a subpixel of a display panel of a display device according to one or more example embodiments of the present disclosure;

FIG. 4 is a plan view showing a scribing area of a display device according to one or more example embodiments of the present disclosure;

FIGS. 5A, 5B, 5C and 5D are example cross-sectional views taken along lines Va-Va, Vb-Vb, Vc-Vc and Vd-Vd, respectively, of FIG. 4;

FIG. 6 is a plan view showing a scribing area of a display device according to one or more example embodiments of the present disclosure;

FIGS. 7A, 7B, 7C and 7D are example cross-sectional views taken along lines VIIa-VIIa, VIIb-VIIb, VIIc-VIIc and VIId-VIId, respectively, of FIG. 6; and

FIG. 8 is a cross-sectional view showing a residue of a metal layer of a scribing area of a display device according to one or more example embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the present disclosure is only defined by scopes of the appended claims.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms "comprise," "have," "include," and the like are used, one or more other elements may be added unless a more limiting term, such as "only," is used. An element described in the singular form is intended to include a plurality of elements, and vice versa, unless the context clearly indicates otherwise. Any implementation described herein as an “example” is not necessarily to be construed as preferred or advantageous over other implementations.

In construing an element, the element is to be construed as including an error or a tolerance range even where no explicit description of such an error or tolerance range is provided.

Where positional relationships are described, for example, where the positional relationship between two parts is described using "on," "over," "under," "above," "below," “beneath,” “near,” “close to,” or “adjacent to,” "beside," "next," or the like, one or more other parts may be located between the two parts unless a more limiting term, such as "immediate(ly)," "direct(ly)," or "close(ly)" is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference. For example, where an element or layer is disposed "on" another element or layer, a third layer or element may be interposed therebetween.

In the case of a description of a temporal relationship, for example, when a temporal precedence is described as 'after', 'following', 'before', 'next', and the like, cases that are not continuous can be included unless a more limiting term, such as 'just', 'directly' or 'immediately' is used.

Although the terms "first," "second," A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term "at least one" should be understood to include all combinations of one or more of related elements. For example, the term of "at least one of first, second and third elements" may include all combinations of two or more of the first, second and third elements as well as the first, second or third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

The term "display device" may include a display device in a narrow sense such as liquid crystal module (LCM), an organic light emitting diode (OLED) module and a quantum dot (QD) module including a display panel and a driving unit for driving the display panel. In addition, the term "display device" may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as "a display device", and an electronic apparatus of a complete product including the LCM, the OLED module and the QD module may be expressed as "a set device." For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example embodiments of the present disclosure where the electric shortage between a plurality of signal lines due to a residual metal layer is minimized, reduced and/or prevented will be described in detail with reference to the accompanying drawings.

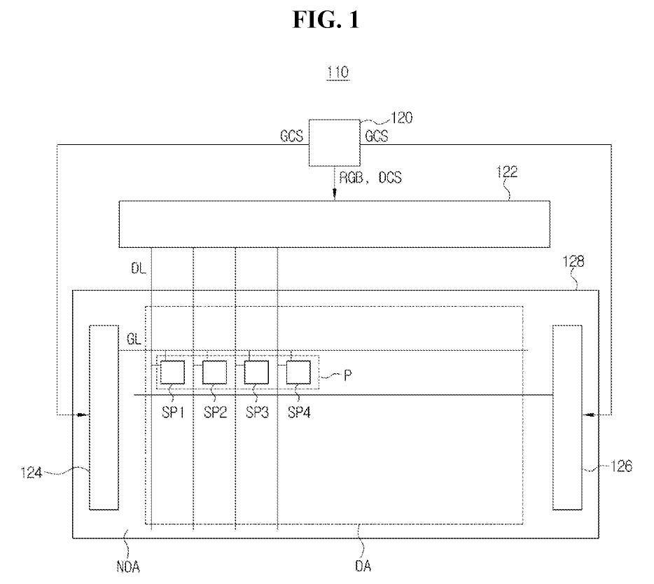

FIG. 1 is a view showing a display device according to one or more example embodiments (for example, a first embodiment) of the present disclosure. Although the display device may be an organic light emitting diode (OLED) display device, it is not limited thereto. For example, the display device may be a quantum dot display device, a micro light emitting diode (LED) display device or a mini light emitting diode (LED) display device.

In FIG. 1, a display device 110 according to one or more example embodiments of the present disclosure includes a timing controlling unit (e.g., circuit) 120, a data driving unit (e.g., circuit) 122, a gate driving unit (for example, without limitation, first and second gate driving units (e.g., circuits) 124 and 126) and a display panel 128.

The timing controlling unit 120 generates an image data RGB, a data control signal DCS and a gate control signal GCS using an image signal and a plurality of timing signals such as a data enable signal, a horizontal synchronization signal, a vertical synchronization signal and a clock signal transmitted from an external system such as a graphic card or a television system. The timing controlling unit 120 transmits the image data RGB and the data control signal DCS to the data driving unit 122, and transmits the gate control signal GCS to the first and second gate driving units 124 and 126.

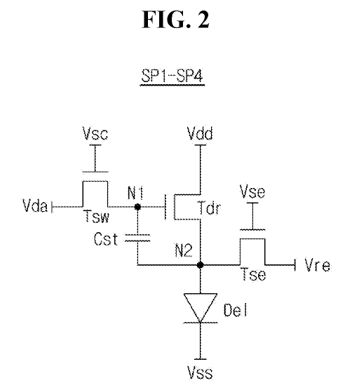

The data driving unit 122 generates a data signal (data voltage) Vda (see FIG. 2) using the image data RGB and the data control signal DCS transmitted from the timing controlling unit 120 and applies the data signal Vda to a data line DL of the display panel 128.

The first and second gate driving units 124 and 126 generate gate signals (gate voltages) Vsc and Vse (see FIG. 2) using the gate control signal GCS transmitted from the timing controlling unit 120 and applies the gate signals Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P, but the present disclosure is not limited thereto. Alternatively, the gate driving units may be manufactured as a driving chip, packaged in a flexible film and attached to the non-display area of the display panel by a tape automated bonding (TAB) method.

Although the first and second gate driving units 124 and 126 are disposed in both side portions of the display panel 128 in one or more example embodiments of FIG. 1, one gate driving unit may be disposed in one side portion of the display panel 128 in another embodiment.

The display panel 128 includes a display area DA at a central portion thereof and a non-display area NDA surrounding the display area DA. In another example, the non-display area NDA may be disposed to be adjacent to the display area DA. The display panel 128 displays an image using the gate signals Vsc and Vse and the data signal Vda. For displaying an image, the display panel 128 includes a plurality of pixels P, a plurality of gate lines GL and a plurality of data lines DL in the display area DA.

Each of the plurality of pixels P may include one or more of first, second, third and fourth subpixels SP1, SP2, SP3 and SP4, and the gate line GL and the data line DL cross each other to define the first, second, third and fourth subpixels SP1, SP2, SP3 and SP4. Each of the first, second, third and fourth subpixels SP1, SP2, SP3 and SP4 is connected to the gate line GL and the data line DL. For example, the first, second, third and fourth subpixels SP1, SP2, SP3 and SP4 may correspond to first, second, third and fourth colors, respectively, and the first, second, third and fourth colors may be red, green, blue and white colors, respectively.

Each of the first, second, third and fourth subpixels SP1, SP2, SP3 and SP4 may include a plurality of transistors such as a switching transistor Tsw (see FIG. 2), a driving transistor Tdr (see FIG. 2) and a sensing transistor Tse (see FIG. 2), a storage capacitor Cst (see FIG. 2) and a light emitting diode Del (see FIG. 2).

FIG. 2 is a circuit diagram showing a subpixel of a display device according to one or more example embodiments of the present disclosure.

In FIG. 2, each of the first, second, third and fourth subpixels SP1, SP2, SP3 and SP4 of the display panel 128 of the display device 110 according to one or more example embodiments of the present disclosure includes a switching transistor Tsw, a driving transistor Tdr, a sensing transistor Tse, a storage capacitor Cst and a light emitting diode Del.

Although each of the first, second, third and fourth subpixels SP1, SP2, SP3 and SP4 has a 3T1C structure having three transistors and one storage capacitor in the example of FIG. 2, each of the first, second, third and fourth subpixels SP1, SP2, SP3 and SP4 may have one of a 6T1C structure having six transistors and one storage capacitor, a 7T1C structure having seven transistors and one storage capacitor and a 8T1C structure having eight transistors and one storage capacitor in another embodiment. In other words, more or less transistors and more or less capacitor may be included in subpixel of the present disclosure.

Although the switching transistor Tsw, the driving transistor Tdr and the sensing transistor Tse may have an N-type in the example of FIG. 2, at least one of the switching transistor Tsw, the driving transistor Tdr and the sensing transistor Tse may have a P-type in another embodiment. For example, each of the switching transistor Tsw, the driving transistor Tdr and the sensing transistor Tse can be configured of one of the P-type and N-type transistors or a combination thereof.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1. However, since the source electrode and the drain electrode can be changed according to an applied voltage, the source electrode and the drain electrode of the transistor are not fixed.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N2 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vda supplied to the first node N1 for one frame and stores a threshold voltage (Vth) of the driving transistor Tdr, such that the variation of the threshold voltage (Vth) of the driving transistor Tdr may be compensated during the display period.

A first capacitor electrode of the storage capacitor Cst is connected to the first node N1, and a second capacitor electrode of the storage capacitor Cst is connected to the second node N2.

The light emitting diode Del emits a light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst may be connected to form the first node N1, and the source electrode of the driving transistor Tdr, the source electrode of the sensing transistor Tse, the second capacitor electrode of the storage capacitor Cst and anode of the light emitting diode Del may be connected to form the second node N2.

The light emitting diode Del may display an image having a luminance corresponding to the image data RGB according to a driving of subpixel circuits of the first, second, third and fourth subpixels SP1, SP2, SP3 and SP4.

A cross-sectional structure of each subpixel SP1, SP2, SP3 and SP4 of the display panel 128 of the display device 110 will be illustrated with reference to a drawing.

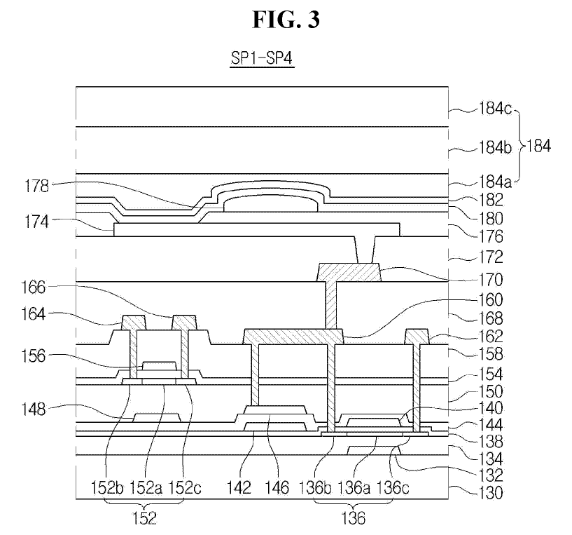

FIG. 3 is a cross-sectional view showing a subpixel of a display panel of a display device according to one or more example embodiments of the present disclosure.

In FIG. 3, a first light shielding pattern 132 is disposed in each of the first, second, third and fourth subpixels SP1, SP2, SP3 and SP4 on a substrate 130, and a first buffer layer 134 is disposed on the first light shielding pattern 132 over the entire substrate 130.

The first light shielding pattern 132 may block a light incident from a lower portion of the substrate 130. For example, the first light shielding pattern 132 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

The first buffer layer 134 may block a moisture or an oxygen permeating from an exterior. For example, the first buffer layer 134 may have a single layer or a multiple layer of an inorganic insulating material such as silicon oxide (SiOx) and silicon nitride (SiNx).

A first semiconductor layer 136 is disposed on the first buffer layer 134 corresponding to the first light shielding pattern 132, and a first gate insulating layer 138 is disposed on the first semiconductor layer 136 over the entire substrate 130.

The first semiconductor layer 136 includes a first channel region 136a not doped with an impurity at a central portion thereof and first source and drain regions 136b and 136c doped with an impurity at both side portions of the first channel region 136a. For example, the first semiconductor layer 136 may include a polycrystalline semiconductor material such as polycrystalline silicon.

For example, the first gate insulating layer 138 may have a single layer or a multiple layer of an inorganic insulating material such as silicon oxide (SiOx) and silicon nitride (SiNx).

A first gate electrode 140 is disposed on the first gate insulating layer 138 corresponding to the first channel region 136a of the first semiconductor layer 136, and a first capacitor electrode 142 separated from the first gate electrode 140 is disposed on the first gate insulating layer 138. A first interlayer insulating layer 144 is disposed on the first gate electrode 140 and the first capacitor electrode 142.

The first gate electrode 140 and the first capacitor electrode 142 may have the same layer and the same material as each other. For example, the first gate electrode 140 and the first capacitor electrode 142 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the first interlayer insulating layer 144 may have a single layer or a multiple layer of an inorganic insulating material such as silicon oxide (SiOx) and silicon nitride (SiNx).

A second capacitor electrode 146 is disposed on the first interlayer insulating layer 144 corresponding to the first capacitor electrode 142, and a second light shielding pattern 148 separated from the second capacitor electrode 146 is disposed on the first interlayer insulating layer 144. A second buffer layer 150 is disposed on the second capacitor electrode 146 and the second light shielding pattern 148 over the entire substrate 130.

The second capacitor electrode 146 and the second light shielding pattern 148 may have the same layer and the same material as each other. For example, the second capacitor electrode 146 and the second light shielding pattern 148 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

The first capacitor electrode 142, the first interlayer insulating layer 144 and the second capacitor electrode 146 may constitute the storage capacitor Cst.

The second buffer layer 150 may block a moisture or an oxygen permeating from an exterior. For example, the second buffer layer 150 may have a single layer or a multiple layer of an inorganic insulating material such as silicon oxide (SiOx) and silicon nitride (SiNx).

A second semiconductor layer 152 is disposed on the second buffer layer 150 corresponding to the second light shielding pattern 148, and a second gate insulating layer 154 is disposed on the second semiconductor layer 152 over the entire substrate 130.

The second semiconductor layer 152 includes a second channel region 152a not conductorized at a central portion thereof and second source and drain regions 152b and 152c conductorized at both side portions of the second channel region 152a. For example, the second semiconductor layer 152 may include an oxide semiconductor material such as indium gallium zinc oxide (IGZO), zinc oxide (ZnO), tin oxide (SnO₂), copper oxide (Cu₂O), nickel oxide (NiO), indium tin zinc oxide (ITZO) and indium aluminum zinc oxide (IAZO).

For example, the second gate insulating layer 154 may have a single layer or a multiple layer of an inorganic insulating material such as silicon oxide (SiOx) and silicon nitride (SiNx).

A second gate electrode 156 is disposed on the second gate insulating layer 154 corresponding to the second channel region 152a of the second semiconductor layer 152, and a second interlayer insulating layer 158 is disposed on the second gate electrode 156 over the entire substrate 130.

For example, the second gate electrode 156 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the second interlayer insulating layer 158 may have a single layer or a multiple layer of an inorganic insulating material such as silicon oxide (SiOx) and silicon nitride (SiNx).

A first source electrode 160, a first drain electrode 162, a second source electrode 164 and a second drain electrode 166 spaced apart from each other are disposed on the second interlayer insulating layer 158, and a first planarizing layer 168 is disposed on the first source electrode 160, the first drain electrode 162, the second source electrode 164 and the second drain electrode 166 over the entire substrate 130.

The first source electrode 160 and the first drain electrode 162 are connected to the first source region 136b and the first drain region 136c, respectively, of the first semiconductor layer 136 through contact holes in the second interlayer insulating layer 158, the second gate insulating layer 154, the second buffer layer 150, the first interlayer insulating layer 144 and the first gate insulating layer 138. The first source electrode 160 is connected to the second capacitor electrode 146 through a contact hole in the second interlayer insulating layer 158, the second gate insulating layer 154 and the second buffer layer 150.

The second source electrode 164 and the second drain electrode 166 are connected to the second source region 152b and the second drain region 152c, respectively, of the second semiconductor layer 152 through contact holes in the second interlayer insulating layer 158 and the second gate insulating layer 154.

The first source electrode 160, the first drain electrode 162, the second source electrode 164 and the second drain electrode 166 may have the same layer and the same material as each other. For example, the first source electrode 160, the first drain electrode 162, the second source electrode 164 and the second drain electrode 166 may have a single layer or a multiple layer of a metallic material such as molybdenum (Mo), aluminum (Al), chromium (Cr), gold (Au), titanium (Ti), nickel (Ni), neodymium (Nd), copper (Cu) and an alloy thereof.

For example, the first planarizing layer 168 may have a single layer or a multiple layer of an organic insulating material such as photoacryl and benzocyclobutene (BCB).

The first semiconductor layer 136, the first gate electrode 140, the first source electrode 160 and the first drain electrode 162 may constitute the driving transistor Tdr, and the second semiconductor layer 152, the second gate electrode 156, the second source electrode 164 and the second drain electrode 166 may constitute the switching transistor Tsw.

A connecting electrode 170 is disposed on the first planarizing layer 168 corresponding to the first source electrode 160, and a second planarizing layer 172 is disposed on the connecting electrode 170 over the entire substrate 130.

The connecting electrode 170 is connected to the first source electrode 160 through a contact hole in the first planarizing layer 168.

For example, the connecting electrode 170 may have a triple layer of a metallic material such as aluminum (Al) and titanium (Ti).

For example, the second planarizing layer 172 may have a single layer or a multiple layer of an organic insulating material such as photoacryl and benzocyclobutene (BCB).

A first electrode 174 is disposed on the second planarizing layer 172 corresponding to the connecting electrode 170, and a bank layer 176 is disposed on the first electrode 174.

The first electrode 174 is connected to the connecting electrode 170 through a contact hole in the second planarizing layer 172.

For example, the first electrode 174 may be an anode and may have a single layer or a multiple layer of a transparent conductive material such as indium tin oxide (ITO) and indium zinc oxide (IZO) or an opaque metallic material such as aluminum (Al), silver (Ag), copper (Cu), lead (Pb), molybdenum (Mo), titanium (Ti) and an alloy thereof.

The bank layer 176 covers an edge portion of the first electrode 174 and has an opening exposing a central portion of the first electrode 174.

For example, the bank layer 176 may have a single layer or a multiple layer of an organic insulating material such as photoacryl and benzocyclobutene (BCB).

Although not shown, when the display device 110 has a top emission type, a metal layer for upwardly reflecting a light downwardly emitted from an emitting layer 180 may be further disposed between the second planarizing layer 172 and the first electrode 174.

For example, the metal layer may include a metallic material and may be a power line.

A spacer 178 is disposed on the bank layer 176, an emitting layer 180 is disposed on the spacer 178 over the entire substrate 130, and a second electrode 182 is disposed on the emitting layer 180 over the entire substrate 130.

For example, the spacer 178 may have a single layer or a multiple layer of an organic insulating material such as photoacryl and benzocyclobutene (BCB).

The emitting layer 180 contacts the first electrode 174 exposed through the opening of the bank layer 176, a sidewall of the opening of the bank layer 176, a top surface of the bank layer 176 and a side surface and a top surface of the spacer 178.

The emitting layer 180 may include a hole assisting layer such as a hole injecting layer and a hole transporting layer, an emitting material layer and an electron assisting layer such as an electron transporting layer and an electron injecting layer.

For example, the second electrode 182 may be a cathode and may have a single layer or a multiple layer of a transparent conductive material such as indium tin oxide (ITO) and indium zinc oxide (IZO) or a half-transmissive or opaque metallic material such as aluminum (Al), silver (Ag), copper (Cu), lead (Pb), magnesium (Mg), molybdenum (Mo), titanium (Ti) and an alloy thereof.

The first electrode 174, the emitting layer 180 and the second electrode 182 may constitute the light emitting diode Del.

An encapsulating layer 184 preventing or reducing a permeation of a moisture is disposed on the second electrode 182 over the entire substrate 130. The encapsulating layer 184 includes a first encapsulating layer 184a, a second encapsulating layer 184b and a third encapsulating layer 184c sequentially disposed on the second electrode 182.

For example, the first encapsulating layer 184a and the third encapsulating layer 184c may have a single layer or a multiple layer of an inorganic insulating material such as silicon oxide (SiOx) and silicon nitride (SiNx), and the second encapsulating layer 184b may include an organic insulating material such as an acryl resin, an epoxy resin, a phenolic resin, a polyamide resin and a polyimide resin.

Although not shown, a metal layer, a third buffer layer, a plurality of bridge patterns spaced apart from each other, a third interlayer insulating layer, a plurality of sensor patterns spaced apart from each other and a protecting layer may be disposed on the encapsulating layer 184 over the entire substrate 130. A touch of a user may be sensed using the plurality of bridge patterns and the plurality of sensor patterns. In addition, the specific structure of the subpixels SP1 to SP4 as shown in FIG. 3 is only described by way of example, and the present disclosure is not limited thereto, and various other structures of the subpixel may be possible when necessary.

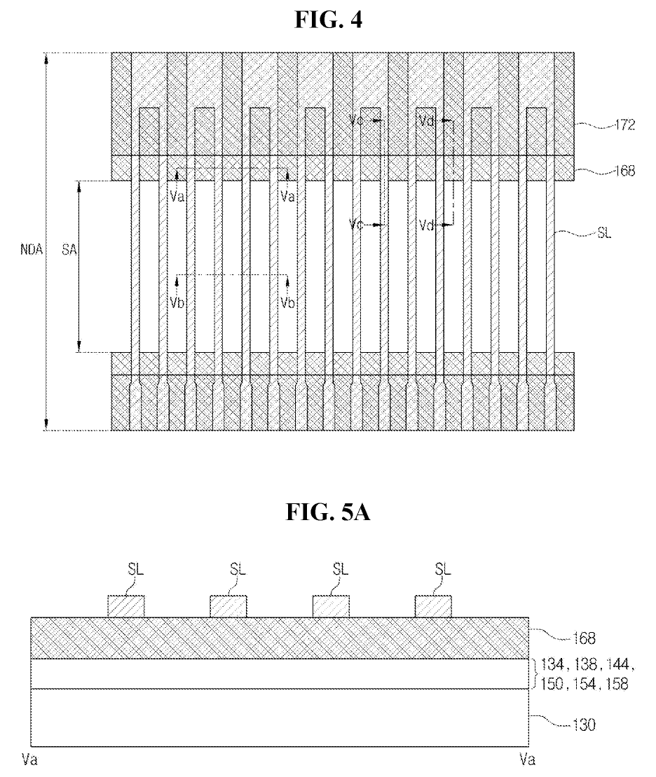

In the display device 110, a plurality of signal lines SL (see FIG. 4) for transmitting power voltages such as the reference signal Vre, the high level signal Vdd and the low level signal Vss and driving signals of the first and second gate driving units 124 and 126 such as a start signal and a clock signal are disposed in the non-display area NDA of the display panel 128. The plurality of signal lines SL may have the same layer and the same material as the connecting electrode 170 between the first and second planarizing layers 168 and 172.

In the display device 110, a pad for connection with the data driving unit 122 is disposed in the non-display area NDA of the display panel 128, and a discharging pattern for preventing or reducing a static electricity is disposed outside the pad to be connected to the pad. The discharging pattern is removed from the pad through a scribing process after the display panel 128 is fabricated.

For success of the scribing process, the first and second planarizing layers 168 and 172 of a scribing area SA (see FIG. 4) having a relatively great thickness are removed. As a result, a relatively great step difference is formed at end portions of the first and second planarizing layers 168 and 172 which constitute a boundary of the scribing area SA, and the plurality of signal lines SL is exposed in the scribing area SA.

When a metal layer is formed on the second planarizing layer 172, the metal layer is not completely removed at step difference portions of the first and second planarizing layers 168 and 172, and a residue of the metal layer is formed. As a result, an electric shortage may occur between the plurality of signal lines SL due to the residue of the metal layer.

In the display device 110 according to one or more example embodiments of the present disclosure, since the end portions of the first and second planarizing layers 168 and 172 are disposed at different positions, the electric shortage is minimized, reduced and/or prevented. The positions of the end portions are not limited to the positions of the end portions of the first and second planarizing layers 168 and 172. The positions of the end portions may be applied to a planarizing layer on a signal line in an area where a driving unit and a display device are connected.

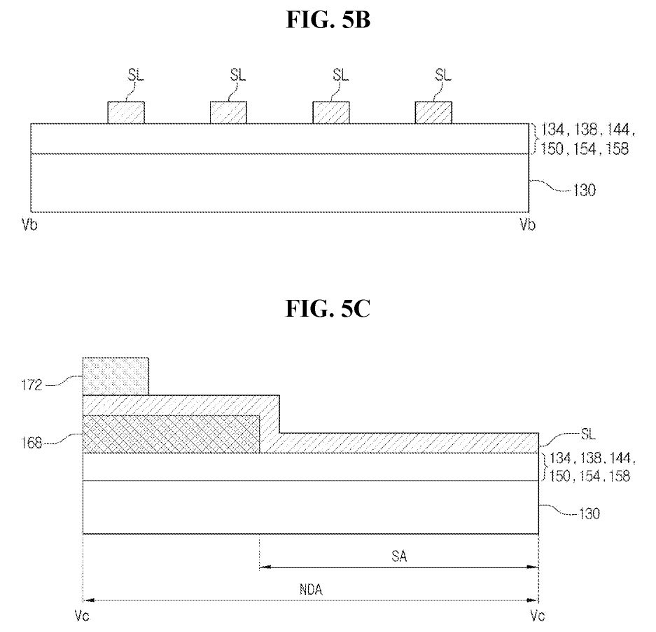

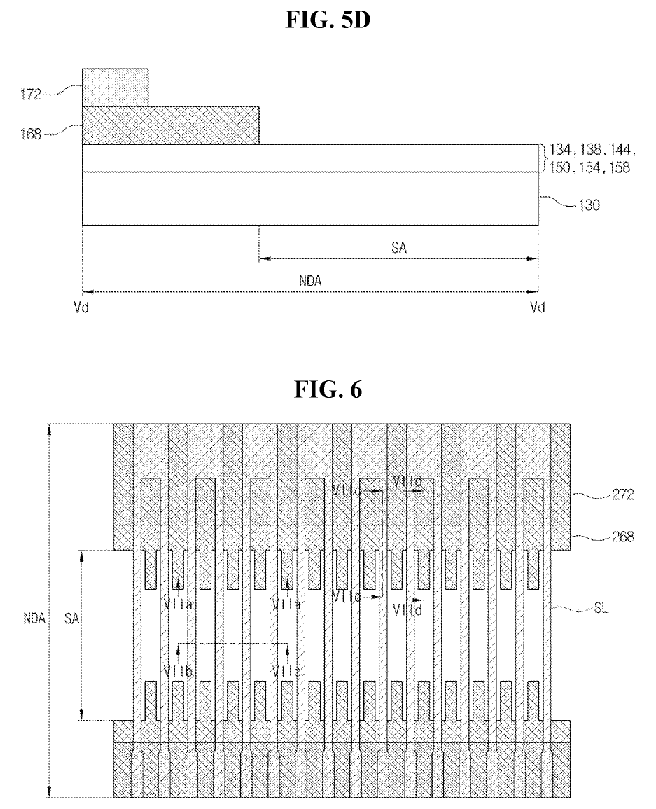

FIG. 4 is a plan view showing a scribing area of a display device according to one or more example embodiments of the present disclosure, and FIGS. 5A, 5B, 5C and 5D are cross-sectional views taken along lines Va-Va, Vb-Vb, Vc-Vc and Vd-Vd, respectively, of FIG. 4.

In FIG. 4, the plurality of signal lines SL spaced apart from each other are disposed in the non-display area NDA of the display panel 128 of the display device 110 according to one or more example embodiments of the present disclosure.

The non-display area NDA includes a scribing area SA corresponding to a cutting line of the substrate 130, and the first and second planarizing layers 168 and 172 are removed in the scribing area SA to expose the plurality of signal lines SL.

An end portion of the first planarizing layer 168 and an end portion of the second planarizing layer 172 are disposed at different positions in the non-display area NDA at an upper portion and a lower portion of the scribing area SA.

The end portion of the first planarizing layer 168 is disposed at a lower portion of the end portion of the second planarizing layer 172 in the non-display area NDA at the upper portion of the scribing area SA, and the end portion of the first planarizing layer 168 is disposed at an upper portion of the end portion of the second planarizing layer 172 in the non-display area NDA at the lower portion of the scribing area SA.

The end portion of the first planarizing layer 168 protrudes from the end portion of the second planarizing layer 172 toward the scribing area SA, and a step difference of the first planarizing layer 168 and a step difference of the second planarizing layer 172 are dispersed as a stair shape. As a result, a residue of a metal layer of a subsequent step of forming the metal layer is minimized, reduced or prevented.

In FIG. 5A, the first buffer layer 134, the first gate insulating layer 138, the first interlayer insulating layer 144, the second buffer layer 150, the second gate insulating layer 154 and the second interlayer insulating layer 158 are sequentially disposed on the substrate 130 in the non-display area NDA at the upper and lower portions of the scribing area SA where the end portion of the first planarizing layer 168 protrude. The first planarizing layer 168 is disposed on the second interlayer insulating layer 158, and the plurality of signal lines SL are disposed on the first planarizing layer 168.

In FIG. 5B, the first buffer layer 134, the first gate insulating layer 138, the first interlayer insulating layer 144, the second buffer layer 150, the second gate insulating layer 154 and the second interlayer insulating layer 158 are sequentially disposed on the substrate 130 in the scribing area SA. The plurality of signal lines SL are disposed on the second interlayer insulating layer 158.

Since the first and second planarizing layers 168 and 172 having a relatively great thickness are removed in the scribing area SA, the substrate 130 may be easily cut.

In FIG. 5C, the first buffer layer 134, the first gate insulating layer 138, the first interlayer insulating layer 144, the second buffer layer 150, the second gate insulating layer 154 and the second interlayer insulating layer 158 are sequentially disposed on the substrate 130. The first planarizing layer 168 is disposed in the non-display area NDA at the upper portion and the lower portion of the scribing area SA. The plurality of signal lines SL are disposed on the first planarizing layer 168 in the non-display area NDA, and the second planarizing layer 172 is disposed on the plurality of signal lines SL in the non-display area NDA.at the upper portion and the lower portion of the scribing area SA.

In the non-display area NDA, at the upper portion and the lower portion of the scribing area SA, the end portion of the first planarizing layer 168 protrudes from the end portion of the second planarizing layer 172 toward the scribing area SA.

When the end portions of the first and second planarizing layers 168 and 172 are disposed at the same positions and the first and second planarizing layers 168 and 172 form one step difference portion of a relatively great size, a residue of a metal layer is formed along the step difference portion with a relatively great thickness. As a result, the adjacent signal lines SL may be electrically connected to each other to cause an electric shortage.

In the display device 110 according to one or more example embodiments of the present disclosure where the end portions of the first and second planarizing layers 168 and 172 are disposed at different positions and the step difference portions of the first and second planarizing layers 168 and 172 are dispersed, a residue of a metal layer is formed along the step difference portions with a relatively small thickness or is not formed. As a result, the electric shortage between the adjacent signal lines SL is minimized, reduced or prevented.

In FIG. 5D, the first buffer layer 134, the first gate insulating layer 138, the first interlayer insulating layer 144, the second buffer layer 150, the second gate insulating layer 154 and the second interlayer insulating layer 158 are sequentially disposed on the substrate 130. The first planarizing layer 168 is disposed on the second interlayer insulating layer 158 in the non-display area NDA at the upper portion and the lower portion of the scribing area SA, and the second planarizing layer 172 is disposed on the first planarizing layer 168 in the non-display area NDA at the upper portion and the lower portion of the scribing area SA.

In the display device 110 according to one or more example embodiments of the present disclosure, since the end portions of the first and second planarizing layers 168 and 172 of the non-display area NDA adjacent to the scribing area SA are disposed at different positions, the step difference portions of the first and second planarizing layers 168 and 172 are dispersed, and the residue of the metal layer is formed along the sept difference portion with a relatively small thickness or is not formed. As a result, the electric shortage between the adjacent signal lines SL is minimized, reduced or prevented.

In another embodiment, the end portions of the first and second planarizing layers are disposed at different positions and the end portion of the first planarizing layer is formed to have a zigzag shape to minimize, reduce or prevent the electric shortage.

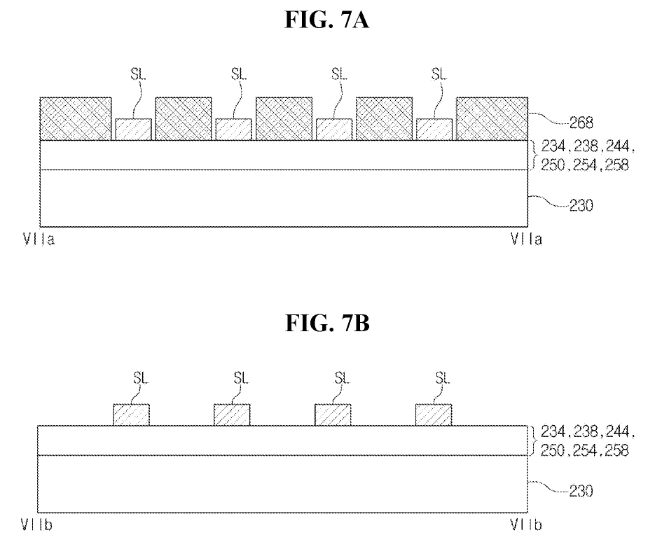

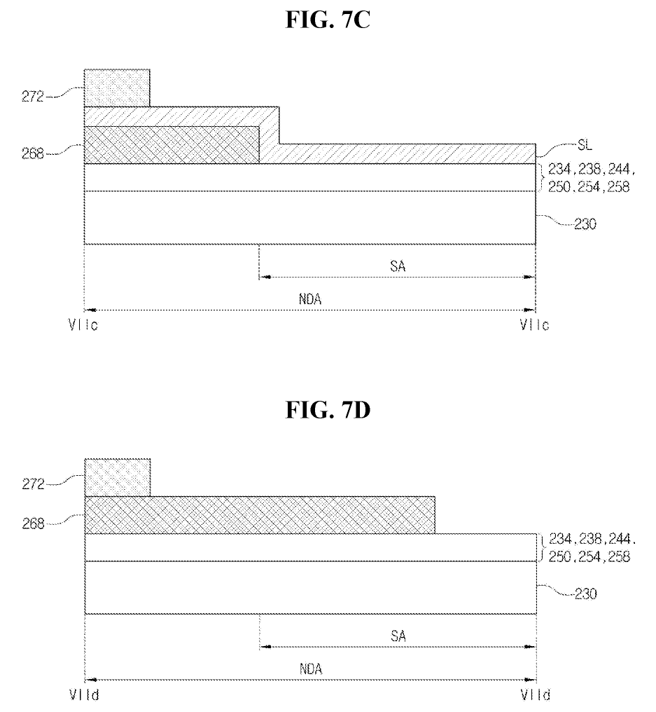

FIG. 6 is a plan view showing a scribing area of a display device according to one or more example embodiments of the present disclosure, and FIGS. 7A, 7B, 7C and 7D are cross-sectional views taken along lines VIIa-VIIa, VIIb-VIIb, VIIc-VIIc and VIId-VIId, respectively, of FIG. 6.

In FIG. 6, a plurality of signal lines SL spaced apart from each other are disposed in a non-display area NDA of a display panel of a display device according to one or more example embodiments of the present disclosure.

The non-display area NDA includes a scribing area SA corresponding to a cutting line of a substrate 230, and first and second planarizing layers 268 and 272 are removed in the scribing area SA to expose a plurality of signal lines SL.

An end portion of the first planarizing layer 268 and an end portion of the second planarizing layer 272 are disposed at different positions in the non-display area NDA at an upper portion and a lower portion of the scribing area SA.

The end portion of the first planarizing layer 268 is disposed at a lower portion of the end portion of the second planarizing layer 272 in the non-display area NDA at the upper portion of the scribing area SA, and the end portion of the first planarizing layer 268 is disposed at an upper portion of the end portion of the second planarizing layer 272 in the non-display area NDA at the lower portion of the scribing area SA.

The end portion of the first planarizing layer 268 protrudes from the end portion of the second planarizing layer 272 toward the scribing area SA, and a step difference of the first planarizing layer 268 and a step difference of the second planarizing layer 272 are dispersed as a stair shape. As a result, a residue of a metal layer of a subsequent step of forming the metal layer is minimized, reduced or prevented.

Further, the end portion of the first planarizing layer 268 has a zigzag shape.

A part between adjacent signal lines SL of the end portion of the first planarizing layer 268 of the non-display area NDA at the upper portion of the scribing area SA protrudes toward a lower portion, and a part between adjacent signal lines SL of the end portion of the first planarizing layer 268 of the non-display area NDA at the lower portion of the scribing area SA protrudes toward an upper portion.

The part corresponding to a space between the adjacent signal lines SL of the end portion of the first planarizing layer 268 protrudes from the other part of the end portion of the first planarizing layer 268 toward the scribing area SA, and a length of the end portion of the first planarizing layer 268 increases. As a result, the connection by the residue of the metal layer of the subsequent step is minimized, reduced or prevented.

In FIG. 7A, a first buffer layer 234, a first gate insulating layer 238, a first interlayer insulating layer 244, a second buffer layer 250, a second gate insulating layer 254 and a second interlayer insulating layer 258 are sequentially disposed on a substrate 230 in an area where the part of the end portion of the first planarizing layer 268 of the scribing area SA protrudes. Protruding portions of the first planarizing layer 268 spaced apart from each other are disposed on the second interlayer insulating layer 258, and the plurality of signal lines SL are disposed on the second interlayer insulating layer 258 between the protruding portions of the first planarizing layer 268, respectively.

A thickness of the first planarizing layer 268 may be greater than a thickness of the signal line SL, and each of the plurality of signal lines SL may be disposed between the protruding portions of the first planarizing layer 268. Accordingly, even when the residue of the metal layer is formed in the subsequent step, the residue of the metal layer on one signal line SL is not directly connected to the residue of the metal layer on the adjacent signal line SL. Accordingly, the electric shortage between the adjacent signal lines SL due to the residue of the metal layer is minimized, reduced and prevented.

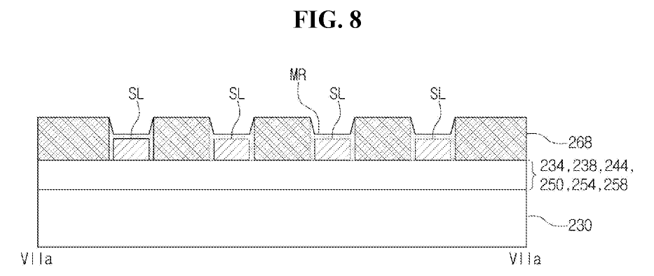

The electric shortage will be illustrated with reference to FIG. 8.

In FIG. 7B, the first buffer layer 234, the first gate insulating layer 238, the first interlayer insulating layer 244, the second buffer layer 250, the second gate insulating layer 254 and the second interlayer insulating layer 258 are sequentially disposed on the substrate 230 in the scribing area SA. The plurality of signal lines SL are disposed on the second interlayer insulating layer 258.

Since the first and second planarizing layers 268 and 272 having a relatively great thickness are removed in the scribing area SA, the substrate 230 may be easily cut.

In FIG. 7C, the first buffer layer 234, the first gate insulating layer 238, the first interlayer insulating layer 244, the second buffer layer 250, the second gate insulating layer 254 and the second interlayer insulating layer 258 are sequentially disposed on the substrate 230. The first planarizing layer 268 is disposed in the non-display area NDA at the upper portion and the lower portion of the scribing area SA. The plurality of signal lines SL are disposed on the first planarizing layer 268 in the non-display area NDA, and the second planarizing layer 272 is disposed on the plurality of signal lines SL in the non-display area NDA.at the upper portion and the lower portion of the scribing area SA.

In the non-display area NDA.at the upper portion and the lower portion of the scribing area SA, the end portion of the first planarizing layer 268 protrudes from the end portion of the second planarizing layer 272 toward the scribing area SA.

When the end portions of the first and second planarizing layers 268 and 272 are disposed at the same positions and the first and second planarizing layers 268 and 272 form one step difference portion of a relatively great size, a residue of a metal layer is formed along the step difference portion with a relatively great thickness. As a result, the adjacent signal lines SL may be electrically connected to each other to cause an electric shortage.

In the display device according to one or more example embodiments of the present disclosure where the end portions of the first and second planarizing layers 268 and 272 are disposed at different positions and the step difference portions of the first and second planarizing layers 268 and 272 are dispersed, a residue of a metal layer is formed along the step difference portions with a relatively small thickness or is not formed. As a result, the electric shortage between the adjacent signal lines SL is minimized, reduced or prevented.

In FIG. 7D, the first buffer layer 234, the first gate insulating layer 238, the first interlayer insulating layer 244, the second buffer layer 250, the second gate insulating layer 254 and the second interlayer insulating layer 258 are sequentially disposed on the substrate 230. The first planarizing layer 268 is disposed on the second interlayer insulating layer 258 in the non-display area NDA at the upper portion and the lower portion of the scribing area SA, and the second planarizing layer 272 is disposed on the first planarizing layer 268 in the non-display area NDA at the upper portion and the lower portion of the scribing area SA.

FIG. 8 is a cross-sectional view showing a residue of a metal layer of a scribing area of a display device according to one or more example embodiments of the present disclosure.

In FIG. 8, the first buffer layer 234, the first gate insulating layer 238, the first interlayer insulating layer 244, the second buffer layer 250, the second gate insulating layer 254 and the second interlayer insulating layer 258 are sequentially disposed on the substrate 230 in an area where the part of the end portion of the first planarizing layer 268 of the scribing area SA protrudes. Protruding portions of the first planarizing layer 268 spaced apart from each other are disposed on the second interlayer insulating layer 258, and the plurality of signal lines SL are disposed on the second interlayer insulating layer 258 between the protruding portions of the first planarizing layer 268, respectively.

The residue MR of the metal layer is formed along the step difference portions of the first and second planarizing layers 268 and 272 in the subsequent step of forming the metal layer. The residue MR of the metal layer may be disposed on the signal line SL between the protruding portions of the first planarizing layer 268.

However, since the protruding portions of the first planarizing layer 268 thicker than the signal line SL are disposed between the adjacent signal lines SL, the residue MR of the metal layer on one signal line SL is not directly connected to the residue MR of the metal layer on the adjacent signal line SL.

In addition, since the end portion of the first planarizing layer 268 has a zigzag shape and a length of the step difference portion of the first planarizing layer 268 increases, a possibility of connection of the residues MR of the metal layer is reduced. As a result, the electric shortage between the adjacent signal lines SL due to the residue MR of the metal layer is minimized, reduced or prevented.

In the display device according to one or more example embodiments of the present disclosure, since the end portions of the first and second planarizing layers 268 and 272 of the non-display area NDA adjacent to the scribing area SA are disposed at different positions, the step difference portions of the first and second planarizing layers 268 and 272 are dispersed, and the residue of the metal layer is formed along the sept difference portion with a relatively small thickness or is not formed. As a result, the electric shortage between the adjacent signal lines SL is minimized, reduced or prevented.

Further, the end portion of the first planarizing layer 268 of the non-display area NDA adjacent to the scribing area SA has a zigzag shape, and the length of the step difference portion of the first planarizing layer 268 increases. As a result, the possibility of connection of the residues MR of the metal layer is reduced, and the electric shortage between the adjacent signal lines SL due to the residue MR of the metal layer is further minimized or reduced and further prevented. Further, the process optimization is obtained.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

WHAT IS CLAIMED IS:

1. A display device, comprising:
a display panel having a display area and a non-display area adjacent to the display area;
a plurality of signal lines spaced apart from each other in the non-display area;
a first planarizing layer under the plurality of signal lines; and
a second planarizing layer on the plurality of signal lines,
wherein the non-display area includes a scribing area where the first and second planarizing layers are removed, and
wherein an end portion of the first planarizing layer and an end portion of the second planarizing layer are disposed at different positions.

2. The display device of claim 1, wherein the end portion of the first planarizing layer protrudes from the end portion of the second planarizing layer toward the scribing area.

3. The display device of claim 1, wherein each of the first and second planarizing layers has either a single layer or multiple layers of an organic insulating material.

4. The display device of claim 1, wherein the end portion of the first planarizing layer has a zigzag shape.

5. The display device of claim 4, wherein a part between the plurality of signal lines of the end portion of the first planarizing layer protrudes from another part of the end portion of the first planarizing layer toward the scribing area.

6. The display device of claim 5, further comprising a metal layer on the second planarizing layer,
wherein a residue of the metal layer is disposed on the plurality of signal lines between protruding portions of the end portion of the first planarizing layer.

7. The display device of claim 4, wherein the end portion of the first planarizing layer includes protruding portions that protrude from other portions of the end portion of the first planarizing layer into the scribing area.

8. The display device of claim 7, wherein each of the protruding portions of the end portion of the first planarizing layer are disposed between two adjacent signal lines among the plurality of signal lines.

9. The display device of claim 1, wherein the plurality of signal lines are disposed in the scribing area between two end portions of the first planarizing layer facing each other.

10. The display device of claim 1, wherein a thickness of the first planarizing layer is greater than a thickness of the plurality of signal lines.

11. The display device of claim 1, wherein a step difference of the first planarizing layer and a step difference of the second planarizing layer are dispersed as a stair shape.

12. The display device of claim 1, further comprising:
a plurality of gate lines and a plurality of data lines in the display area, the plurality of gate lines and the plurality of data lines crossing each other to define a plurality of subpixels; and
a pixel circuit unit in each of the plurality of subpixels.

13. The display device of claim 12, wherein the pixel circuit unit includes at least one thin film transistor and a light emitting diode,
wherein the at least one thin film transistor includes a semiconductor layer, a gate insulating layer on the semiconductor layer, a gate electrode on the gate insulating layer corresponding to the semiconductor layer, an interlayer insulating layer on the gate electrode, a source electrode and a drain electrode on the interlayer insulating layer, and
wherein the light emitting diode includes a first electrode, a bank layer on the first electrode, an emitting layer on the bank layer, and a second electrode on the emitting layer.

14. The display device of claim 13, wherein the first planarizing layer is disposed on the source electrode and the drain electrode,
wherein a connecting electrode connected between the first electrode and the source electrode or between the first electrode and the drain electrode of the at least one thin film transistor is disposed on the first planarizing layer, and
wherein the second planarizing layer is disposed on the connecting electrode.

15. The display device of claim 14, wherein a metal layer is disposed between the second planarizing layer and the first electrode.

16. The display device of claim 13, wherein a first encapsulating layer of an inorganic insulating material, a second encapsulating layer of an organic insulating material and a third encapsulating layer of an inorganic insulating material are sequentially disposed on the second electrode.

17. The display device of claim 13, wherein the interlayer insulating layer and the gate insulating layer are sequentially disposed under the plurality of signal lines.

18. A display device, comprising:
a substrate having a display area and a non-display area adjacent to the display area;
a plurality of signal lines spaced apart from each other in the non-display area;
a first planarizing layer under the plurality of signal lines; and
a second planarizing layer on the plurality of signal lines,
wherein in the non-display area, an end portion of the first planarizing layer and an end portion of the second planarizing layer are disposed at different positions, and the plurality of signal lines extend beyond the end portion of the first planarizing layer and the end portion of the second planarizing layer.
